(19) United States
(12) Patent Application Publication
(10) Pub. No.: US 2023/0067340 A1
(43) Pub. Date: Mar. 2, 2023

(54) LIGHT EMITTING DEVICE AND METHOD OF MANUFACTURING THE SAME

(71) Applicant: SONY SEMICONDUCTOR SOLUTIONS CORPORATION, Kanagawa (JP)

(72) Inventors: Suguru SAITO, Kanagawa (JP); Yuichi YAMAMOTO, Kanagawa (JP); Nobutoshi FUJII, Kanagawa (JP); Taizo TAKACHI, Kanagawa (JP)

(73) Assignee: SONY SEMICONDUCTOR SOLUTIONS CORPORATION, Kanagawa (JP)

(21) Appl. No.: 17/797,956

(22) PCT Filed: Jan. 6, 2021
(86) PCT No.: PCT/JP2021/000257

§ 371 Date: Aug. 5, 2022

(30) Foreign Application Priority Data
Feb. 19, 2020 (JP) 2020-026500

(51) Int. Cl. H01S 5/02253; H01S 5/02355; H01S 5/42; H01S 5/02

(52) U.S. Cl. CPC H01S 5/02253; H01S 5/02355; H01S 5/423; H01S 5/021; G01S 7/4814

(57) ABSTRACT

There are provided a light emitting device capable of forming a light emitting element on a suitable substrate and a method of manufacturing the same.

A light emitting device according to the present disclosure includes: a first substrate; a plurality of light emitting elements that are provided on a first surface of the first substrate; and a second substrate that is provided on a second surface of the first substrate opposite to the first surface.

### TECHNICAL FIELD

The present disclosure relates to a light emitting device and a method of manufacturing the same.

### BACKGROUND ART

As a type of semiconductor laser, there is known a surface emitting laser such as a VCSEL (Vertical Cavity Surface Emitting Laser). Generally, in a light emitting device using a surface emitting laser, a plurality of light emitting elements are provided in a two-dimensional array on the front surface or the back surface of a substrate.

### CITATION LIST

### Patent Literature

### [PTL 1]

JP 2004-526194 T

### SUMMARY

### Technical Problem

The above-mentioned light emitting device is formed on the surface of a semiconductor substrate such as a GaAs (gallium arsenide) substrate. In this case, since the GaAs substrate is weak in strength, the GaAs substrate may be cracked or chipped during the manufacture of the light emitting device. Thus, there is an issue of what kind of substrate a light emitting element is to be formed on.

Therefore, the present disclosure provides a light emitting device capable of forming a light emitting element on a suitable substrate and a method of manufacturing the same.

### Solution to Problem

A light emitting device according to a first aspect of the present disclosure includes: a first substrate; a plurality of light emitting elements that are provided on a first surface of the first substrate; and a second substrate that is provided on a second surface of the first substrate opposite to the first surface. This makes it possible to form the light emitting elements on the suitable first substrate, for example, to form the light emitting elements on the first substrate reinforced by the second substrate.

Further, in this first aspect, the first substrate may be formed of a first material, and the second substrate may be formed of a second material different from the first material. This makes it possible, for example, to use the second substrate that is harder in strength than the first substrate.

Further, in this first aspect, the second substrate may be directly bonded to the first substrate. This makes it possible, for example, to make the refraction and reflection of light between the first substrate and the second substrate less likely to occur.

Further, in this first aspect, the first substrate may contain gallium (Ga) and arsenic (As). This makes it possible, for example, to adopt the first substrate suitable for the light emitting device.

Further, in this first aspect, the second substrate may be a semiconductor substrate containing silicon (Si). This makes it possible, for example, to obtain the second substrate at a low cost.

Further, in this first aspect, the second substrate may have a third surface on the first substrate side and a fourth surface opposite to the first substrate, and the light emitting device may further include a plurality of lenses that are provided on the fourth surface of the second substrate and on which light emitted from the light emitting elements is incident. This makes it possible for the lenses to shape the light from the light emitting elements.

Further, in this first aspect, the lenses may be provided on the fourth surface of the second substrate as part of the second substrate. This makes it possible, for example, to form as part of the second substrate the lenses on the second substrate, which is hard in strength than the first substrate.

Further, in this first aspect, the lenses may include at least one of a concave lens, a convex lens, and a flat lens. This makes it possible, for example, to shape the light with the appropriate lenses according to the purpose of using the light.

Further, in this first aspect, the plurality of light emitting elements and the plurality of lenses may have a one-to-one correspondence so that the light emitted from one light emitting element enters one lens corresponding to the one light emitting element. This makes it possible to shape the light from the plurality of light emitting elements for each light emitting element.

Further, in this first aspect, the light emitted from the plurality of light emitting elements may be transmitted through the first substrate from the first surface to the second surface, transmitted through the second substrate from the third substrate to the fourth surface, and then enter the plurality of lenses. This makes it possible to implement a structure in which light passes through the first and second substrates and is then output from the light emitting device.

Further, in this first aspect, the first surface of the first substrate may be a front surface of the first substrate, and the second surface of the first substrate may be a back surface of the first substrate. This makes it possible to provide a back-emission type of light emitting device.

Further, in this first aspect, the second substrate may have a third surface on the first substrate side and a fourth surface opposite to the first substrate, and an area of the third surface of the second substrate may be larger than an area of the second surface of the first substrate. This makes it possible for the second substrate to more effectively prevent damage to the first substrate.

Further, in this first aspect, the second substrate may be bonded to the first substrate via a resin film. This makes it possible, for example, to easily bond the second substrate to the first substrate.

Further, the light emitting device according to this first aspect may further include a plurality of second lenses that are provided on the second surface of the first substrate and on which light emitted from the light emitting elements is incident. This makes it possible for the second lenses to shape the light from the light emitting elements.

Further, in this first aspect, the second lenses may include at least one of a concave lens and a convex lens. This makes it possible, for example, to shape the light with the appropriate second lenses according to the purpose of using the light.

Further, the light emitting device according to this first aspect may further include a recess that is provided on the fourth surface of the second substrate, and the lenses may be provided on a bottom surface of the recess. This makes it possible to bring the lenses closer to the light emitting elements.

Further, the light emitting device according to the first aspect may further include a reflective film that is provided on a side surface of the recess. This makes it possible to efficiently utilize the light incident on the side surface of the recess from the second substrate.

A method of manufacturing a light emitting device according to a second aspect of the present disclosure includes: bonding a second substrate to a second surface of a first substrate; and forming a plurality of light emitting elements on a first surface of the first substrate opposite to the second surface. This makes it possible to form the light emitting elements on the suitable first substrate, for example, to form the light emitting elements on the first substrate reinforced by the second substrate.

Further, in this second aspect, the second substrate may have a third surface on the first substrate side and a fourth surface opposite to the first substrate, and the method of manufacturing the light emitting device may further include forming, on the fourth surface of the second substrate, a plurality of lenses on which light emitted from the light emitting elements is incident. This makes it possible for the lenses to shape the light from the light emitting elements.

Further, in this second aspect, the lenses may include at least one of a concave lens, a convex lens, and a flat lens. This makes it possible, for example, to shape the light with the appropriate lenses according to the purpose of using the light.

Further, in this second aspect, the concave lens may be formed by forming a protrusion on the second surface of the second substrate and processing the protrusion into a recess. This makes it possible to form the concave lens by processing from the protrusion to the recess.

Further, in this second aspect, the convex lens may be formed by forming a protrusion on the second surface of the second substrate. This makes it possible, for example, to form the convex lens by a small number of steps.

Further, in this second aspect, the first substrate may include a wafer and an epitaxial layer formed on a surface of the wafer, and the second substrate may be bonded to a surface of the epitaxial layer of the first substrate after the epitaxial layer is formed on the surface of the wafer. This makes it possible, for example, to provide the appropriate bonding in consideration of the linear expansion coefficients of the first and second substrates.

Further, in this second aspect, the second substrate may be directly bonded to the first substrate. This makes it possible, for example, this makes it possible, for example, to make the refraction and reflection of light between the first substrate and the second substrate less likely to occur.

### BRIEF DESCRIPTION OF DRAWINGS

FIG. 1 is a block diagram illustrating a configuration of a distance measuring device according to a first embodiment.

FIG. 2 is a cross-sectional view illustrating a structure example of the distance measuring device according to the first embodiment.

FIG. 3 is a cross-sectional view illustrating a structure of the distance measuring device illustrated in B of FIG. 2.

FIG. 4 is a cross-sectional view illustrating a structure of the light emitting device according to the first embodiment.

FIG. 5 is a plan view illustrating the structure of the light emitting device according to the first embodiment.

FIG. 6 is a cross-sectional view illustrating a structure of a light emitting device by way of a comparative example in the first embodiment.

FIG. 7 is a cross-sectional view illustrating a structure of a light emitting device by way of a first modification, according to the first embodiment.

FIG. 8 is a cross-sectional view illustrating a structure of a light emitting device by way of a second modification, according to the first embodiment.

FIG. 9 is a cross-sectional view illustrating a structure of a light emitting device by way of a third modification, according to the first embodiment.

FIG. 10 is a cross-sectional view illustrating a structure of a light emitting device by way of a fourth modification, according to the first embodiment.

FIG. 11 is a cross-sectional view illustrating a structure of a light emitting device by way of a fifth modification, according to the first embodiment.

FIG. 12 is a cross-sectional view illustrating a structure of a light emitting device by way of a sixth modification, according to the first embodiment.

FIG. 13 is a cross-sectional view illustrating a structure of a light emitting device by way of a seventh modification, according to the first embodiment.

FIG. 14 is a cross-sectional view illustrating a structure of a light emitting device by way of an eighth modification, according to the first embodiment.

FIG. 15 is a cross-sectional view illustrating a structure example of the light emitting device by way of the eighth modification, according to the first embodiment.

FIG. 16 is a cross-sectional view illustrating a structure of a light emitting device by way of a ninth modification, according to the first embodiment.

FIG. 17 is a cross-sectional view (1/3) illustrating a method of manufacturing the light emitting device according to the second embodiment.

FIG. 18 is a cross-sectional view (2/3) illustrating the method of manufacturing the light emitting device according to the second embodiment.

FIG. 19 is a cross-sectional view (3/3) illustrating the method of manufacturing the light emitting device according to the second embodiment.

FIG. 20 is a cross-sectional view for explaining the details of a step illustrated in B of FIG. 17.

FIG. 21 is a cross-sectional view for explaining the details of a step illustrated in C of FIG. 19.

FIG. 22 is a cross-sectional view (1/2) illustrating a method of manufacturing the light emitting device according to the third embodiment.

FIG. 23 is a cross-sectional view (2/2) illustrating the method of manufacturing the light emitting device according to the third embodiment.

FIG. 24 is a cross-sectional view for explaining the details of a step illustrated in B of FIG. 23.

FIG. 25 is a cross-sectional view illustrating a method of manufacturing a light emitting device by way of a modification according to the third embodiment.

FIG. 26 is a cross-sectional view illustrating a method 1 which is different from the method illustrated in A of FIG. 22 to B of FIG. 23.

FIG. 27 is a cross-sectional view illustrating a method 2 which is different from the method illustrated in A of FIG. 22 to B of FIG. 23.

### DESCRIPTION OF EMBODIMENTS

Embodiments of the present disclosure will be described below with reference to the drawings.

### First Embodiment

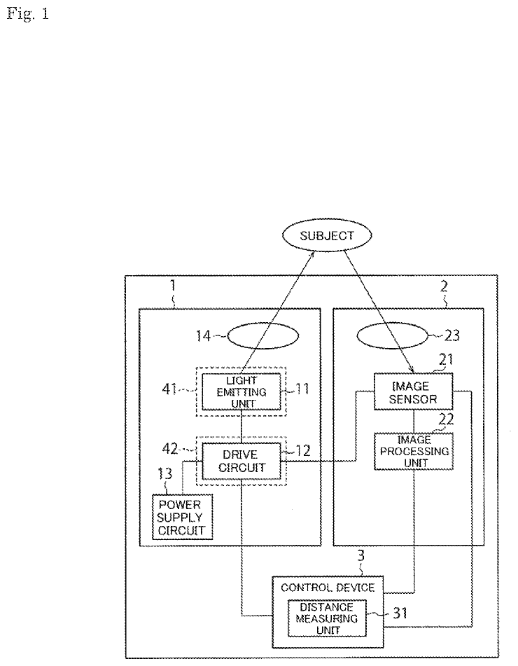

FIG. 1 is a block diagram illustrating a configuration of a distance measuring device according to a first embodiment.

The distance measuring device of FIG. 1 includes a light emitting device 1, an image pickup device 2, and a control device 3. In the distance measuring device of FIG. 1, a subject is irradiated with light emitted from the light emitting device 1, the image pickup device 2 receives the light reflected by the subject to capture an image of the subject, and the control device 3 measures (calculates) a distance to the subject by using an image signal output from the image pickup device 2. The light emitting device 1 functions as a light source for the image pickup device 2 to capture an image of the subject.

The light emitting device 1 includes a light emitting unit 11, a drive circuit 12, a power supply circuit 13, and a light emitting optics system 14. The image pickup device 2 includes an image sensor 21, an image processing unit 22, and an image pickup optics system 23. The control device 3 includes a distance measuring unit 31.

The light emitting unit 11 emits laser light for irradiating the subject. As will be described later, the light emitting unit 11 in the present embodiment includes a plurality of light emitting elements arranged in a two-dimensional array in which each light emitting element has a VCSEL structure. The subject is irradiated with the light emitted from these light emitting elements. Further, the light emitting unit 11 in the present embodiment is provided in a chip called an LD (Laser Diode) chip 41.

The drive circuit 12 is an electric circuit for driving the light emitting unit 11. The power supply circuit 13 is an electric circuit for generating a power supply voltage for the drive circuit 12. In the distance measuring device according to the present embodiment, for example, the power supply circuit 13 generates a power supply voltage from an input voltage supplied from a battery in the distance measuring device, and the drive circuit 12 drives the light emitting unit 11 by using this power supply voltage. Further, the drive circuit 12 in the present embodiment is provided in a substrate called an LDD (Laser Diode Driver) substrate 42.

The light emitting optics system 14 includes various optical elements, and irradiates the subject with light from the light emitting unit 11 through these optical elements. Similarly, the image pickup optics system 23 includes various optical elements, and receives light from the subject through these optical elements.

The image sensor 21 receives light from the subject through the image pickup optics system 23, and converts this light into an electric signal by photoelectric conversion. The image sensor 21 is, for example, a CCD (Charge Coupled Device) sensor or a CMOS (Complementary Metal Oxide Semiconductor) sensor. The image sensor 21 in the present embodiment converts that electronic signal from an analog signal to a digital signal by A/D (Analog to Digital) conversion, and outputs an image signal as the digital signal to the image processing unit 22. Further, the image sensor 21 in the present embodiment outputs a frame synchronization signal to the drive circuit 12, and the drive circuit 12 causes the light emitting unit 11 to emit light at a timing corresponding to the frame cycle of the image sensor 21 based on the frame synchronization signal.

The image processing unit 22 performs various image processing on the image signal output from the image sensor 21. The image processing unit 22 includes, for example, an image processing processor such as a DSP (Digital Signal Processor).

The control device 3 controls various operations of the distance measuring device of FIG. 1, for example, controls the light emitting operation of the light emitting device 1 and the image capture operation of the image pickup device 2. The control device 3 includes, for example, a CPU (Central Processing Unit), a ROM (Read Only Memory), a RAM (Random Access Memory), and the like.

The distance measuring unit 31 measures a distance to the subject based on the image signal output from the image sensor 21 and subjected to image processing by the image processing unit 22. The distance measuring unit 31 employs as a distance measuring method, for example, an STL (Structured Light) method or a ToF (Time of Flight) method. The distance measuring unit 31 may further measure a distance between the distance measuring device and the subject for each part of the subject based on the above-mentioned image signal to identify the three-dimensional shape of the subject.

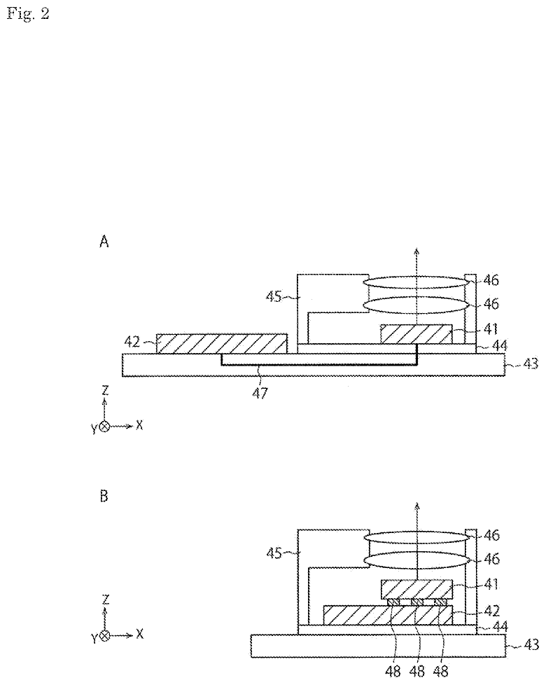

FIG. 2 is a cross-sectional view illustrating a structure example of the distance measuring device according to the first embodiment.

In A of FIG. 2, a structure of the distance measuring device according to the present embodiment is illustrated by way of a first example. The distance measuring device of this example includes the above-mentioned LD chip 41 and LDD substrate 42, a mounting substrate 43, a heat dissipation substrate 44, a correction lens holder 45, one or more correction lenses 46, and a wire 47.

In A of FIG. 2, an X-axis, a Y-axis, and a Z-axis that are perpendicular to each other are illustrated. The X and Y-directions correspond to the lateral directions (horizontal direction), and the Z direction corresponds to the longitudinal direction (vertical direction). Further, the +Z direction corresponds to the upward direction, and the −Z direction corresponds to the downward direction. The −Z direction may or may not exactly coincide with the direction of gravity.

The LD chip 41 is disposed on the mounting substrate 43 via the heat dissipation substrate 44, and the LDD substrate 42 is also disposed on the mounting substrate 43. The mounting substrate 43 is, for example, a printed circuit board. On the mounting substrate 43 in the present embodiment, the image sensor 21 and the image processing unit 22 of FIG. 1 are also arranged. The heat dissipation substrate 44 is, for example, a ceramic substrate such as an AlN (aluminum nitride) substrate.

The correction lens holder 45 is disposed on the heat dissipation substrate 44 so as to surround the LD chip 41, and holds the one or more correction lenses 46 above the LD chip 41. These correction lenses 46 are included in the light emitting optics system 14 (FIG. 1) described above. The light emitted from the light emitting unit 11 (FIG. 1) in the LD chip 41 is corrected by these correction lenses 46 and then emitted to the subject (FIG. 1). As an example, two correction lenses 46 held by the correction lens holder 45 are illustrated in Ain FIG. 2.

The wire 47 is provided on the front surface, the back surface, the inside, and the like of the mounting substrate 41, and is electrically connected to the LD chip 41 and the LDD substrate 42. The wire 47 includes, for example, printed wires provided on the front surface and the back surface of the mounting substrate 41, and via wires penetrating the mounting substrate 41. The wire 47 in the present embodiment further passes through the inside or the vicinity of the heat dissipation substrate 44.

In B of FIG. 2, a structure of the distance measuring device according to the present embodiment is illustrated by way of a second example. The distance measuring device of this example includes the same components as the distance measuring device of the first example, except that it includes bumps 48 instead of the wire 47.

In B of FIG. 2, the LDD substrate 42 is disposed on the heat dissipation substrate 44, and the LD chip 41 is disposed on the LDD substrate 42. Disposing the LD chip 41 on the LDD substrate 42 in this way makes it possible to reduce the size of the mounting substrate 44 as compared with the case of the first example. In B of FIG. 2, the LD chip 41 is disposed on the LDD substrate 42 via the bumps 48, and is electrically connected to the LDD substrate 42 by the bumps 48.

Hereinafter, the distance measuring device according to the present embodiment will be described as having the structure of the second example illustrated in B of FIG. 2. However, the following description is also applicable to the distance measuring device having the structure of the first example, except for the description of the structure peculiar to the second example.

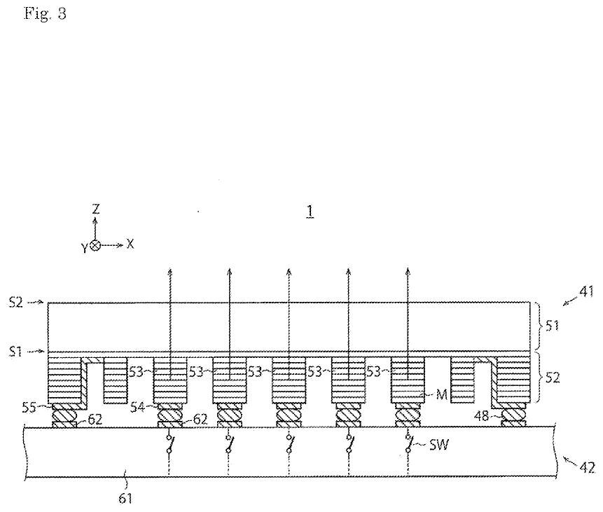

FIG. 3 is a cross-sectional view illustrating the structure of the distance measuring device illustrated in B of FIG. 2.

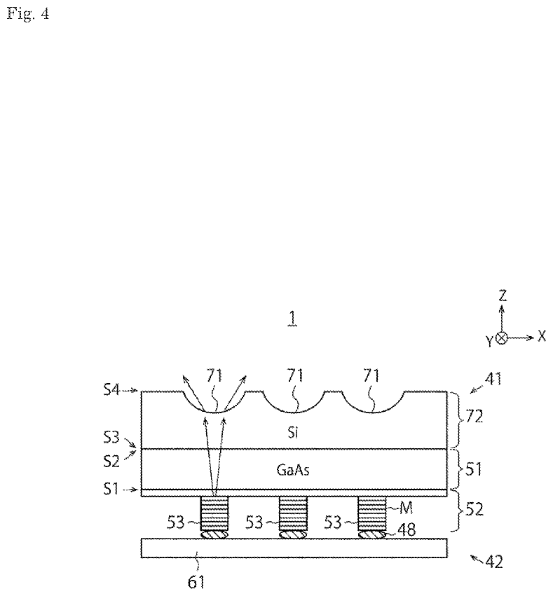

FIG. 3 illustrates a cross section of the LD chip 41 and the LDD substrate 42 in the light emitting device 1. As illustrated in FIG. 3, the LD chip 41 includes a substrate 51, a laminated film 52, a plurality of light emitting elements 53, a plurality of anode electrodes 54, and a plurality of cathode electrodes 55. Further, the LDD substrate 42 includes a substrate 61 and a plurality of connection pads 62. It is to be noted that, in FIG. 3, lenses 71 and a substrate 72, which will be described later, are not illustrated (see FIG. 4).

The substrate 51 is, for example, a semiconductor substrate, and in the present embodiment, it is a GaAs (gallium arsenide) substrate. The substrate 51 is an example of a first substrate in the present disclosure. FIG. 3 illustrates a front surface S1 of the substrate 51 facing the −Z direction and a back surface S2 of the substrate 51 facing the +Z direction. The front surface S1 is an example of a first surface in the present disclosure. The back surface S2 is an example of a second surface opposite to the first surface in the present disclosure.

The laminated film 52 includes a plurality of layers laminated on the front surface S1 of the substrate 51. Examples of these layers include an n-type semiconductor layer, an active layer, a p-type semiconductor layer, a light reflection layer, an insulating layer having a light emission window, and the like. The laminated film 52 includes a plurality of mesa portions M protruding in the −Z direction. Parts of these mesa portions M form the plurality of light emitting elements 53.

The plurality of light emitting elements 53 are provided on the front surface S1 of the substrate 52 as part of the laminated film 52. Each light emitting element 53 in the present embodiment has a VCSEL structure and emits light in the +Z direction. As illustrated in FIG. 3, the light emitted from each light emitting element 53 is transmitted through the substrate 51 from the front surface S1 to the back surface S2, and then enters the correction lenses 46 (FIG. 2) from the substrate 51. In this way, the LD chip 41 in the present embodiment is a back-emission type of VCSEL chip.

The anode electrodes 54 are formed on the lower surfaces of the light emitting elements 53. The cathode electrodes 55 are formed on the lower surfaces of the mesa portions M other than those for the light emitting elements 53, and extend to the lower surface of the laminated film 52 between the mesa portions M. Each light emitting element 53 emits light by a current flowing between the anode electrode 54 and the corresponding cathode electrode 55.

As described above, the LD chip 41 is disposed on the LDD substrate 42 via the bumps 48, and is electrically connected to the LDD substrate 42 by the bumps 48. Specifically, the connection pads 62 are formed on the substrate 61 included in the LDD substrate 42, and the mesa portions M are arranged on the connection pads 62 via the bumps 48. Each mesa portion M is disposed on the bump 48 via the anode electrode 54 or the cathode electrode 55. The substrate 61 is, for example, a semiconductor substrate, and in the present embodiment, it is a Si (silicon) substrate.

The LDD substrate 42 includes the drive circuit 12 for driving the light emitting unit 11 (FIG. 1). FIG. 3 schematically illustrates a plurality of switch SWs included in the drive circuit 12. Each switch SW is electrically connected to the corresponding light emitting element 53 via the bump 48. The drive circuit 12 in the present embodiment can control (on/off) these switch SWs for each individual switch SW. Thus, the drive circuit 12 can drive the plurality of light emitting elements 53 for each individual light emitting element 53. This makes it possible to precisely control the light emitted from the light emitting unit 11, for example, to cause only the light emitting element 53 required for distance measurement to emit light. Such individual control of the light emitting elements 53 is feasible by disposing the LDD substrate 42 below the LD chip 41 so that each light emitting element 53 can be easily electrically connected to the corresponding switch SW.

FIG. 4 is a cross-sectional view illustrating a structure of the light emitting device 1 according to the first embodiment.

FIG. 4 illustrates a cross section of the LD chip 41 and the LDD substrate 42 in the light emitting device 1. As described above, the LD chip 41 includes the substrate 51, the laminated film 52, the plurality of light emitting elements 53, the plurality of anode electrodes 54, and the plurality of cathode electrodes 55, and the LDD substrate 42 includes the substrate 61 and the plurality of connection pads 62. However, in FIG. 4, the anode electrodes 54, the cathode electrodes 55, and the connection pads 62 are not illustrated.

The LD chip 41 in the present embodiment includes a substrate 72 on the back surface S2 of the substrate 51 in addition to the plurality of light emitting elements 53 on the front surface S1 of the substrate 51. The substrate 72 is, for example, a semiconductor substrate, and in the present embodiment, it is a Si (silicon) substrate. As described above, the material (Si) forming the substrate 72 is different from the material (GaAs) forming the substrate 51. The substrate 72 is an example of a second substrate in the present disclosure. The substrate 72 in the present embodiment is directly bonded to the substrate 51 without interposing another film or layer. FIG. 4 illustrates a front surface S3 of the substrate 72 facing the −Z direction and a back surface S4 of the substrate 72 facing the +Z direction. The front surface S3 is an example of a third surface in the present disclosure. The back surface S4 is an example of a fourth surface in the present disclosure. The front surface S3 is located on the substrate 51 side, and the back surface S4 is located on the opposite side of the substrate 51.

The LD chip 41 in the present embodiment further includes a plurality of lenses 71 on the back surface S4 of the substrate 72. As with the light emitting elements 53, these lenses 71 are arranged in a two-dimensional array. The lenses 71 in the present embodiment have a one-to-one correspondence with the light emitting elements 53, and each of the lenses 71 is disposed in the +Z direction of one light emitting element 53.

The lenses 71 in the present embodiment are provided on the back surface S4 of the substrate 72 as part of the substrate 72. Specifically, the lens 71 in the present embodiment are a concave lens, and is formed as a part of the substrate 72 by etching the back surface S4 of the substrate 72 into a recessed shape. According to the present embodiment, the lenses 71 can be easily formed by processing the substrate 72.

The light emitted from the plurality of light emitting elements 53 is transmitted through the substrate 51 from the front surface S1 to the back surface S2, transmitted through the substrate 72 from the front surface S3 to the back surface S4, and enters the plurality of lenses 71. In the present embodiment, as illustrated in FIG. 4, the light emitted from each light emitting element 53 enters one lens 71 corresponding to the light emitting element 53. This makes it possible for the corresponding lens 71 to shape the light emitted from each light emitting element 53. The light passing through these lenses 71 passes through the correction lenses 46 (FIG. 2), so that the subject (FIG. 1) is irradiated with that light.

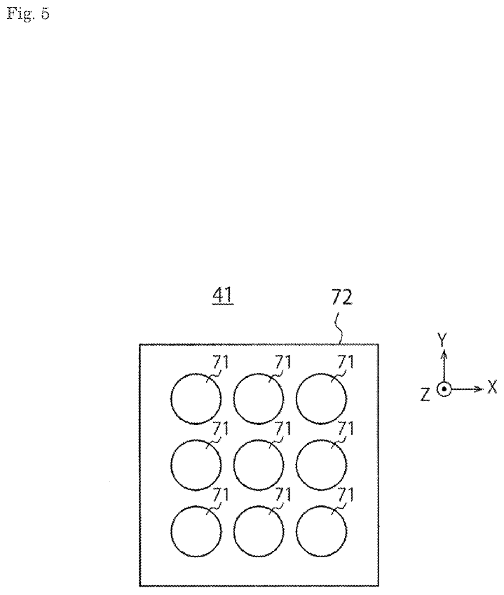

FIG. 5 is a plan view illustrating the structure of the light emitting device 1 according to the first embodiment.

FIG. 5 illustrates an example of the layout of the lenses 71 illustrated in FIG. 4. In FIG. 5, 3×3 lenses 71 are arranged in a two-dimensional array on the back surface S4 of the substrate 72, specifically, in a square grid pattern. Each lens 71 is disposed in the +Z direction of the corresponding light emitting element 53 (FIG. 4). It is to be noted that the number of lenses 71 of the light emitting device 1 according to the present embodiment may be any number, and the arrangement of the lenses 71 of the light emitting device 1 according to the present embodiment does not have to be a square grid pattern.

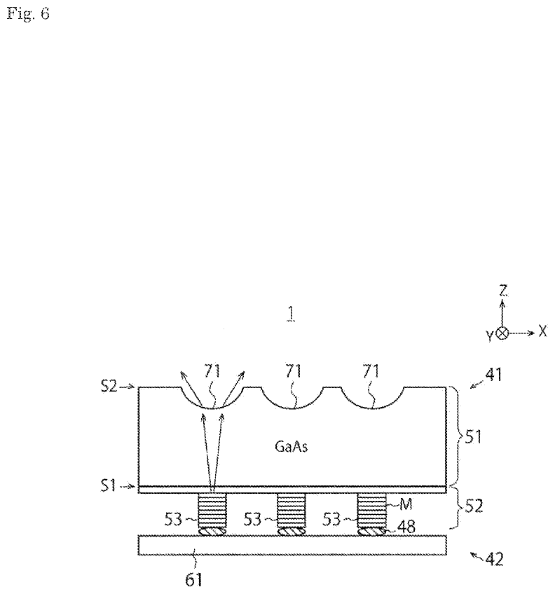

FIG. 6 is a cross-sectional view illustrating a structure of a light emitting device 1 by way of a comparative example in the first embodiment.

An LD chip 41 in this comparative example includes a plurality of light emitting elements 53 on a front surface S1 of a substrate 51, but does not include a substrate 72 on a back surface S2 of the substrate 51. The substrate 51 in this comparative example is a GaAs substrate, as with the substrate 51 of the first embodiment. The LD chip 41 in this comparative example further includes a plurality of lenses 71 on the back surface S2 of the substrate 51.

Hereinafter, the light emitting device 1 according to the first embodiment illustrated in FIG. 4 will be compared with the light emitting device 1 of the comparative example illustrated in FIG. 6.

The substrate 51 of the comparative example illustrated in FIG. 6 is a GaAs substrate. The GaAs substrate has an advantage that it is suitable for forming light emitting elements 53, but has a defect that it is weak in strength. Specifically, the Young's modulus of the GaAs substrate is 83 MPa, which means that the mechanical strength of the GaAs substrate is low. Accordingly, during the manufacturing of the light emitting device 1, the substrate 51 may be damaged, such as the substrate 51 being cracked or chipped. Damage to the substrate 51 is likely to occur, for example, when the substrate 51 is thinned, when the lenses 71 are formed, when the LD chip 41 (substrate 51) is placed on the LDD substrate 42 (substrate 61), and the like.

Similarly, the substrate 51 in the first embodiment illustrated in FIG. 4 is also a GaAs substrate. Therefore, the substrate 51 in the present embodiment is also suitable for forming the light emitting elements 53. However, the substrate 51 in the present embodiment is bonded to the substrate 72. The substrate 72 in the present embodiment is a Si substrate. The Young's modulus of the Si substrate is 190 MPa, which means the mechanical strength of the Si substrate is high. Therefore, according to the present embodiment, bonding the substrate 51 to the substrate 72 makes it possible to enjoy the advantages of the GaAs substrate while suppressing the defects of the GaAs substrate. Further, using a Si substrate as the substrate 72 has an advantage that the GaAs substrate can be reinforced with, for example, an inexpensively available Si substrate. The Si substrate also has the advantages of high thermal conductivity and excellent heat dissipation. The thermal conductivity of the GaAs substrate is 55 W/mK, and the refractive index of the Si substrate is 157 W/mK.

The substrate 51 in the present embodiment is thinned after being joined to the substrate 72, for example, as will be described later. This makes it possible to prevent damage to the substrate 51 when the substrate 51 is thinned. Further, the lenses 71 in the present embodiment are formed not on the substrate 51 but on the substrate 72. This means that the substrate 51 is not to be processed when the lenses 71 are formed, so that it is possible to prevent damage to the substrate 51. Further, when the lenses 71 are formed, the substrate 51 is already bonded to the substrate 72, which also contributes to the prevention of damage to the substrate 51. The same applies to when the LD chip 41 is placed on the LDD substrate 42.

In this way, according to the present embodiment, it is possible to form the light emitting elements 53 on the suitable substrate 51, for example, to form the light emitting elements 53 on the substrate 51 reinforced by the substrate 72. It is to be noted that the substrate 51 may be a substrate other than the GaAs substrate, and may be, for example, a compound semiconductor substrate other than the GaAs substrate. Further, the substrate 72 may be a substrate other than the Si substrate, and may be, for example, a silicon-based substrate other than the Si substrate. However, when the GaAs substrate and the Si substrate are used as the substrate 51 and the substrate 72, the refractive index of the GaAs substrate and the refractive index of the Si substrate are close to each other, and there is an advantage that the refraction or reflection of light between the GaAs substrate and the Si substrate are less likely to occur. At the laser emission wavelength of 940 nm of the light emitting elements 53 in the present embodiment, the refractive index of the GaAs substrate is 3.5, and the refractive index of the Si substrate is 3.5 to 3.6.

It is to be noted that, as described above, the substrate 72 in the present embodiment is directly bonded to the substrate 51 without interposing another film or layer. For example, the substrate 72 in the present embodiment is directly bonded to the substrate 51 without using an adhesive. This makes it possible to make the refraction and reflection of light between the substrate 51 and the substrate 72 much less likely to occur. However, for example, when the refraction or reflection of light does not matter so much, or when the refractive index of an adhesive is close to the refractive index of the substrates 51 and 72, the substrate 72 may be bonded to the substrate 51 using the adhesive. Further details of bonding the substrate 51 and the substrate 72 will be described later.

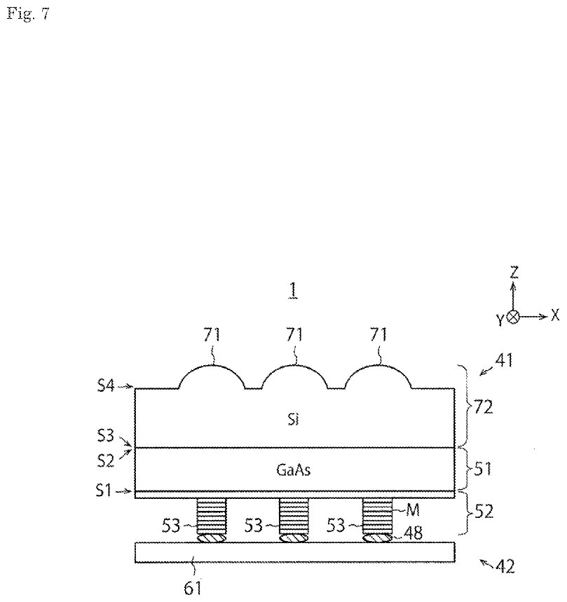

FIG. 7 is a cross-sectional view illustrating a structure of a light emitting device 1 by way of a first modification, according to the first embodiment.

The lenses 71 in FIG. 4 are concave lenses, while the lenses 71 in FIG. 7 are convex lenses. The lenses 71 in this modification are also formed on the back surface S4 of the substrate 72 as part of the substrate 72. The light emitted from each light emitting element 53 is transmitted through the substrate 51 from the front surface S1 to the back surface S2, transmitted through the substrate 72 from the front surface S3 to the back surface S4, and enters the corresponding lens 71.

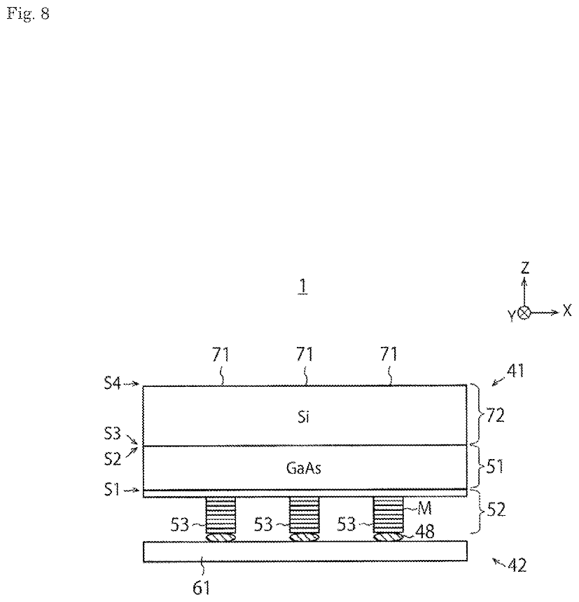

FIG. 8 is a cross-sectional view illustrating a structure of a light emitting device 1 by way of a second modification, according to the first embodiment.

The lenses 71 in FIG. 4 are concave lenses, while the lenses 71 in FIG. 8 are flat lenses. The flat lens is a lens having a flat surface and provides a flat lens surface directly above the corresponding light emitting element 53. The light from the corresponding light emitting element 53 enters this flat lens surface. The state in which the flat lenses are present above the light emitting elements 53 can also be said to be the state in which there is no lens above the light emitting elements 53. The lenses 71 in this modification are also formed on the back surface S4 of the substrate 72 as part of the substrate 72.

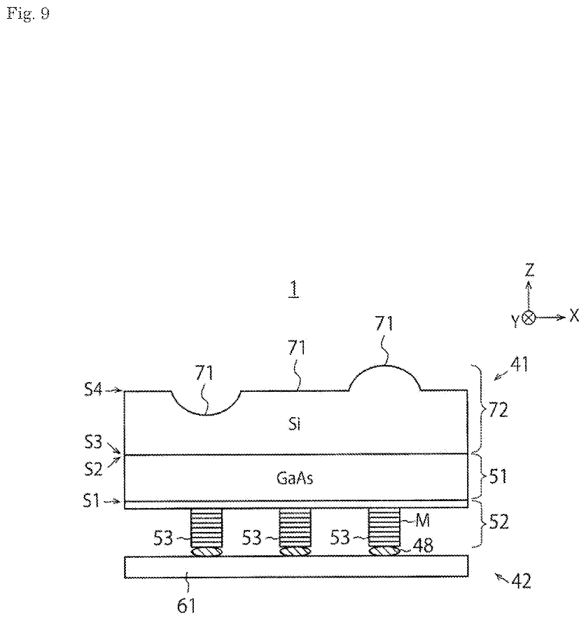

FIG. 9 is a cross-sectional view illustrating a structure of a light emitting device 1 by way of a third modification, according to the first embodiment.

The lenses 71 in this modification include two or more types of lenses, for example, a concave lens, a flat lens, and a convex lens. The lenses 71 in this modification are also formed on the back surface S4 of the substrate 72 as part of the substrate 72. The light emitted from each light emitting element 53 is transmitted through the substrate 51 from the front surface S1 to the back surface S2, transmitted through the substrate 72 from the front surface S3 to the back surface S4, and enters the corresponding lens 71.

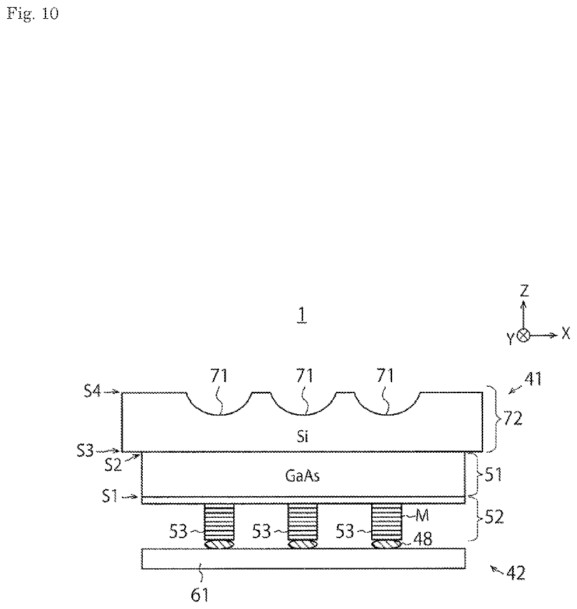

FIG. 10 is a cross-sectional view illustrating a structure of a light emitting device 1 by way of a fourth modification, according to the first embodiment.

In this modification, the area of the front surface S3 of the substrate 72 is set to be larger than the area of the back surface S2 of the substrate 51. Specifically, the shapes of the front surface S1, the back surface S2, the front surface S3, and the back surface S4 in this modification are all square or rectangular, and the sides in the X-direction and the sides in the Y-direction of the front surface S3 are set to be longer than the sides in the X-direction and the sides in the Y-direction of the back surface S2, respectively. Such a structure can be provided, for example, when the substrates 51 and 72 are diced, by dicing the substrates 51 and 72 so that the back surface S2 of the substrate 51 is larger than the front surface S3 of the substrate 72. In FIG. 10, the right side surface of the substrate 72 protrudes to the right from the right side surface of the substrate 51, and the left side surface of the substrate 72 protrudes to the left from the left side surface of the substrate 51.

According to this modification, for example, adopting such a structure makes it possible to, for example, when the LD chip 41 is conveyed by a conveying device, prevent the conveying device from coming into contact with the substrate 51. In other words, it is possible to convey the LD chip 41 in a state where the conveying device is in contact with the substrate 72 and not with the substrate 51. This makes it possible to more effectively prevent damage to the substrate 72.

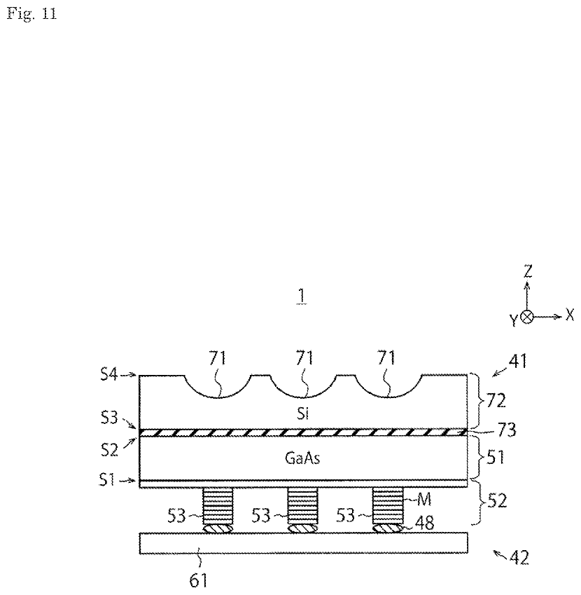

FIG. 11 is a cross-sectional view illustrating a structure of a light emitting device 1 by way of a fifth modification, according to the first embodiment.

The substrate 72 in this modification is bonded to the substrate 51 via a resin film 73. This makes it possible, for example, to easily bond the substrate 72 to the substrate 51. The resin film 73 may be any film as long as it can transmit light from the light emitting elements 53, but it is desirable that the resin film 73 has a refractive index close to the refractive indexes of the substrates 51 and 72. This makes it possible to make the refraction and reflection of light between the substrate 51 and the substrate 72 less likely to occur. It is to be noted that the resin film 73 does not have to have a refractive index close to the refractive indexes of the substrates 51 and 72 when the refraction or reflection of light does not matter so much.

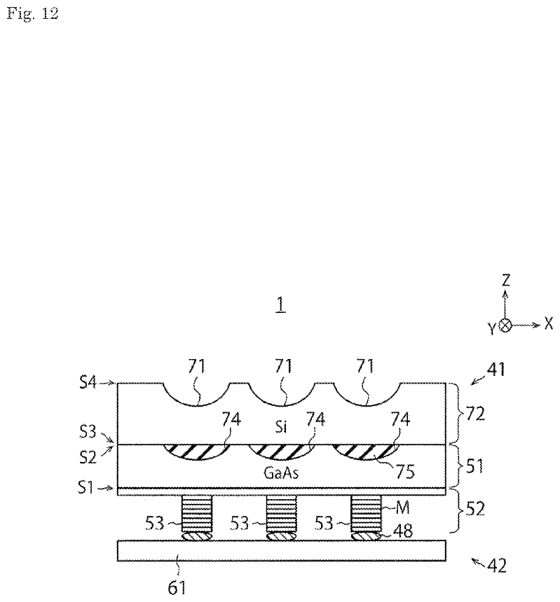

FIG. 12 is a cross-sectional view illustrating a structure of a light emitting device 1 by way of a sixth modification, according to the first embodiment.

The light emitting device 1 according to this modification includes a plurality of lenses 74 provided on the back surface S2 of the substrate 51. The lenses 74 are, for example, concave lenses. The lenses 74 in this modification are provided on the back surface S2 of the substrate 51 as part of the substrate 71. The lens 74 is an example of a second lens in the present disclosure.

The light emitting device 1 of this modification further includes a plurality of embedded films 75 embedded in the recesses of these concave lenses (lenses 74). The embedded film 75 may be any film as long as it can transmit light from the light emitting elements 53, but it is desirable that the embedded film 75 has a refractive index close to the refractive indexes of the substrates 51 and 72. The embedded film 75 may be formed of, for example, the same material as the resin film 73 described above.

The lenses 74 in this modification have a one-to-one correspondence with the light emitting elements 53 and the lenses 71, and each of the lenses 74 is disposed in the +Z direction of one light emitting element 53 and the −Z direction of one lens 71. The light emitted from each light emitting element 53 is transmitted through the substrate 51 from the front surface S1 to the back surface S2, transmitted through one lens 74 corresponding to the light emitting element 53, transmitted through the substrate 72 from the front surface S3 to the back surface S4, and enters one lens 71 corresponding to the light emitting element 53. This makes it possible for the corresponding lenses 74 and 71 to shape the light emitted from each light emitting element 53.

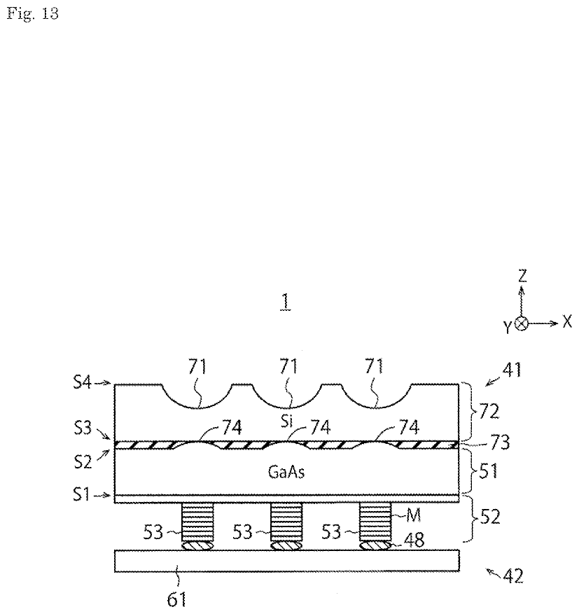

FIG. 13 is a cross-sectional view illustrating a structure of a light emitting device 1 by way of a seventh modification, according to the first embodiment.

The light emitting device 1 according to this modification includes a plurality of lenses 74 provided on the back surface S2 of the substrate 51, as with the light emitting device 1 according to the sixth modification. However, the lenses 74 in this modification are, for example, convex lenses. The lenses 74 in this modification are also provided on the back surface S2 of the substrate 51 as part of the substrate 71.

The substrate 72 in this modification is bonded to the substrate 51 via a resin film 73, as with the substrate 51 in the fifth modification. In addition, the lenses 74 in this modification are covered with the resin film 73. In this way, the resin film 73 in this modification has not only the function of bonding the substrate 72 to the substrate 51 but also the function of embedding the lenses 74.

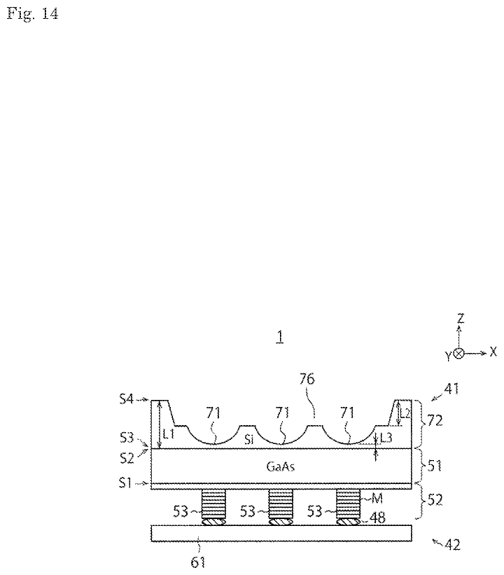

FIG. 14 is a cross-sectional view illustrating a structure of a light emitting device 1 by way of an eighth modification, according to the first embodiment.

The light emitting device 1 according to this modification includes a recess 76 provided on the back surface S4 of the substrate 72, and a plurality of lenses 71 as described above are provided on the bottom surface of the recess 76. This makes it possible to bring each lens 71 closer to the corresponding light emitting element 53. Bringing the lens 71 closer to the light emitting element 53 has an advantage that the diffusion of light between the light emitting element 53 and the lens 71 can be reduced.

FIG. 14 illustrates a thickness L1 of the substrate 72, a depth L2 of the recess 76, and a distance L3 between the lowermost of the lenses 71 and the front surface S3 of the substrate 72. According to this modification, the deeper the depth L2 of the recess 76 is, the shorter the distance L3 can be. This makes it possible to bring each lens 71 closer to the corresponding light emitting element 53.

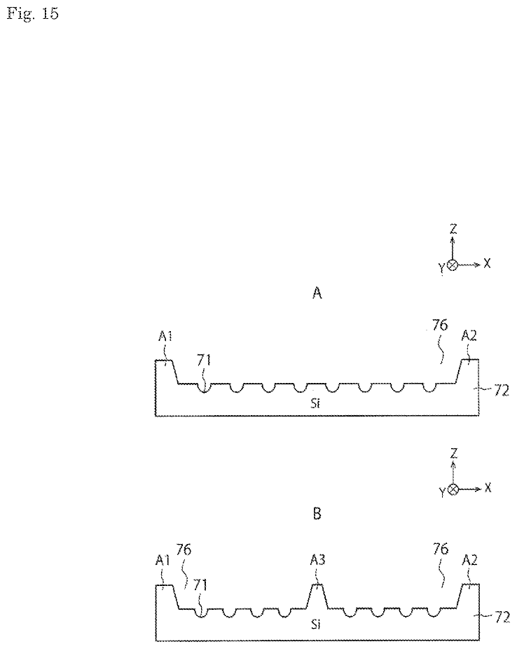

FIG. 15 is a cross-sectional view illustrating a structure example of the light emitting device 1 by way of the eighth modification, according to the first embodiment.

The example in A of FIG. 15 illustrates a substrate 72 in which one recess 76 is provided. Reference character A1 indicates a side wall portion forming a side surface of the recess 76. Reference character A2 indicates another side wall portion forming a side surface of the recess 76. The substrate 72 in this example has one side wall that annularly surrounds the recess 76. The side wall portion A1 and the side wall portion A2 in A of FIG. 15 are portions of the side wall and connected to each other. It is to be noted that it is desirable that the side wall has a sufficient thickness such that the side wall is not cracked or chipped.

The example in B of FIG. 15 illustrates a substrate 72 in which a plurality of recesses 76 are provided. Reference character A3 indicates a side wall portion forming a side surface of these recesses 76, as with reference characters A1 and A2. The substrate 72 in this example has one side wall that surrounds these recesses 76 in mesh. The side wall portion A1, the side wall portion A2, and the side wall portion A3 in B of FIG. 15 are portions of the side wall and connected to each other. It is to be noted that it is desirable that the side wall has a sufficient thickness such that the side wall is not cracked or chipped.

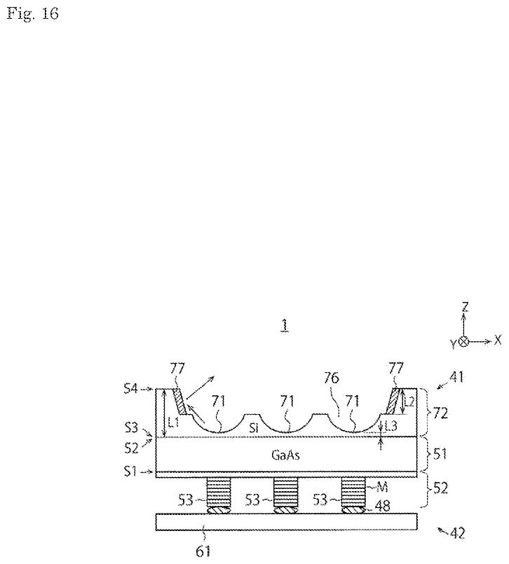

FIG. 16 is a cross-sectional view illustrating a structure of a light emitting device 1 by way of a ninth modification, according to the first embodiment.

The light emitting device 1 according to this modification includes a recess 76 provided on the back surface S4 of the substrate 72, and a plurality of lenses 71 as described above are provided on the bottom surface of the recess 76, as with the light emitting device 1 according to the eighth modification. The light emitting device 1 according to this modification further includes at least one reflective metal film 77 provided on the side surface of the recess 76. The reflective metal film 77 is an example of a reflective film in the present disclosure.

The reflective metal film 77 is a metal layer such as a Ti (titanium) layer, an Al (aluminum) layer, or a Cu (copper) layer, and has a function of reflecting light. This makes it possible to reflect the light directed from the surfaces of the lenses 71 toward the side surface of the recess 76 by the reflective metal film 77 and cause that light to enter the correction lenses 46 (FIG. 2). As a result, it is possible to improve the luminous efficiency of the light emitting device 1.

Although various modifications of the first embodiment have been described above, two or more of these modifications may be combined to be implemented. For example, the recess 76 in the eighth or ninth modification may be provided on the substrate 72 in the sixth or seventh modification. Further, the lens 71 in any of the fourth to ninth modifications may be a convex lens instead of a concave lens.

As described above, the light emitting device 1 according to the present embodiment includes the substrate (Si substrate) 72 provided on the back surface S2 of the substrate (GaAs substrate) 51. Thus, according to the present embodiment, it is possible to form the light emitting elements 53 on the suitable substrate 51, for example, to form the light emitting elements 53 on the substrate 51 reinforced by the substrate 72.

### Second Embodiment

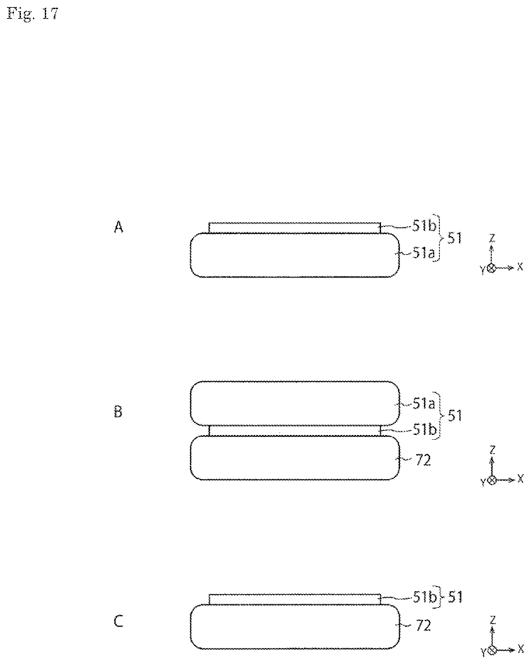

FIGS. 17 to 19 are cross-sectional views illustrating a method of manufacturing the light emitting device 1 according to a second embodiment.

First, the substrate 51 is prepared for manufacturing the light emitting device 1 (A of FIG. 17). The substrate 51 illustrated in A of FIG. 17 includes a wafer 51a and an epitaxial layer 51b formed on the upper surface of the wafer 51a. The wafer 51a in the present embodiment is a GaAs substrate (GaAs wafer), and the epitaxial layer 51b in the present embodiment is a GaAs layer formed on the wafer 51a by epitaxial growth. The epitaxial layer 51b is formed on the wafer 51a by high-temperature heat treatment.

Next, after the substrate 51 is turned upside down, the substrate 51 is directly bonded to the upper surface of the substrate 72 (B of FIG. 17). The substrate 72 illustrated in B of FIG. 17 is a Si substrate (Si wafer). In the present embodiment, a surface of the epitaxial layer 51b is bonded to the upper surface of the substrate 72. In B of FIG. 17, the surface (lower surface) of the epitaxial layer 51b corresponds to the back surface S2 of the substrate 51, and the upper surface of the substrate 72 corresponds to the front surface S3 of the substrate 72.

The wafer 51a in the present embodiment is a GaAs substrate (GaAs wafer), and has a linear expansion coefficient of 5.7×10⁻⁶/K, for example. On the other hand, the substrate 72 in the present embodiment is a Si substrate (Si wafer), and has a linear expansion coefficient of 3.9×10⁻⁶/K, for example. Considering these linear expansion coefficients, it is desirable that the epitaxial growth of the epitaxial layer 51b performed by the high temperature heat treatment is to be performed before the bonding between the substrate 51 and the substrate 72. Accordingly, in the present embodiment, the step A of FIG. 17 is performed before the step B of FIG. 17. The epitaxial layer 51b is used to form the light emitting elements 53, as will be described later.

Next, the substrate 51 is thinned (C of FIG. 17). As a result, the wafer 51a is removed, and the epitaxial layer 51b remains on the substrate 72. In C of FIG. 17, the upper surface of the epitaxial layer 51b corresponds to the front surface Si of the substrate 51. In the present embodiment, the substrate 51 is thinned in a state where its strength is increased by direct bonding, so that it is possible to suppress the substrate 51 from being chipped or cracked.

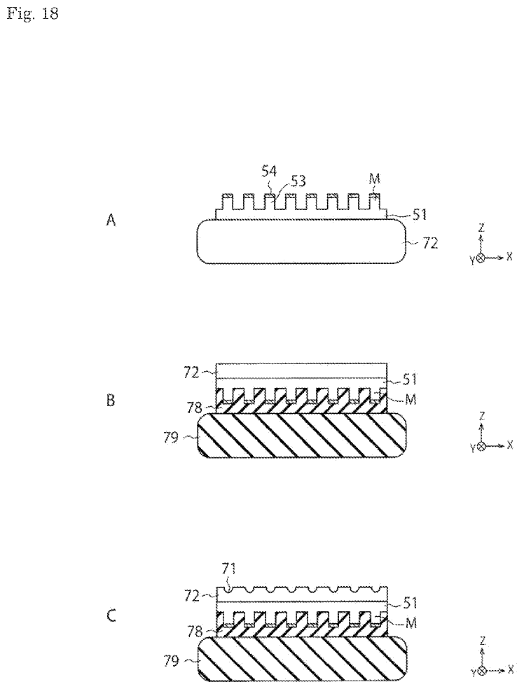

Next, the laminated film 52, the plurality of light emitting elements 53, the plurality of anode electrodes 54, the plurality of cathode electrodes 55, and so on are formed on the upper surface of the substrate 51 (epitaxial layer 51b) (A of FIG. 18). Note that the laminated film 52 and the cathode electrodes 55 are not illustrated. In A of FIG. 18, the plurality of mesa portions M described above are further illustrated. In the present embodiment, these mesa portions M are formed by dry etching, lens diaphragms are formed, an insulating film is formed, and anode electrodes 54 and cathode electrodes 55 are formed.

Next, a resin film 78 is formed on the upper surface of the substrate 51 so as to cover the mesa portions M and so on, and then the substrate 51 and the substrate 72 are turned upside down to temporarily bond the substrate 51 to the upper surface of a glass substrate 79 (B of FIG. 18). The glass substrate 79 is also referred to as a temporary substrate. The resin film 78 is, for example, an adhesive. Next, the substrate 72 is thinned (B of FIG. 18). In B of FIG. 18, the upper surface of the substrate 72 corresponds to the back surface S4 of the substrate 72. In the present embodiment, the substrate 72 having high mechanical strength is thinned, so that it is possible to suppress the substrate 51 and the substrate 72 from being chipped or cracked.

Next, the plurality of lenses 71 are formed on the upper surface of the substrate 72 (C of FIG. 18). In the present embodiment, these lenses 71 are formed as part of the substrate 72 by processing the upper surface of the substrate 72. Each lens 71 in the present embodiment is formed above the corresponding light emitting element 53 so that the light emitted from the corresponding light emitting element 53 enters the lens 71. The lenses 71 are concave lenses in C of FIG. 18, but other types of lenses may be used. It is to be noted that, in the case where the lenses 71 are flat lenses, the step C of FIG. 18 is unnecessary. The lenses 71 in the present embodiment are formed by lithography and dry etching.

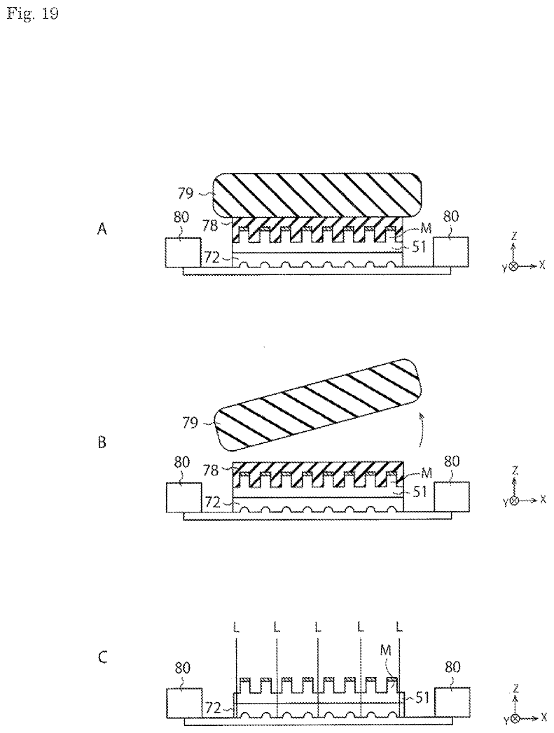

Next, the substrate 51 and the substrate 72 are turned upside down, and then the substrate 72 is mounted on a dicing tape of a mounting device 80 (A of FIG. 19). Next, the glass substrate 79 is peeled off from the substrate 51 (B of FIG. 19). Next, the resin film 78 is removed by cleaning, and the substrate 51 and the substrate 72 are diced (C of FIG. 19). In C of FIG. 19, dicing lines L for cutting the substrate 51 and the substrate 72 for dicing are illustrated.

In this way, the LD chip 41 in the present embodiment is manufactured. The LD chip 41 is then disposed on the LDD substrate 42 via the plurality of bumps 48. In this way, the light emitting device 1 illustrated in FIG. 4 is manufactured.

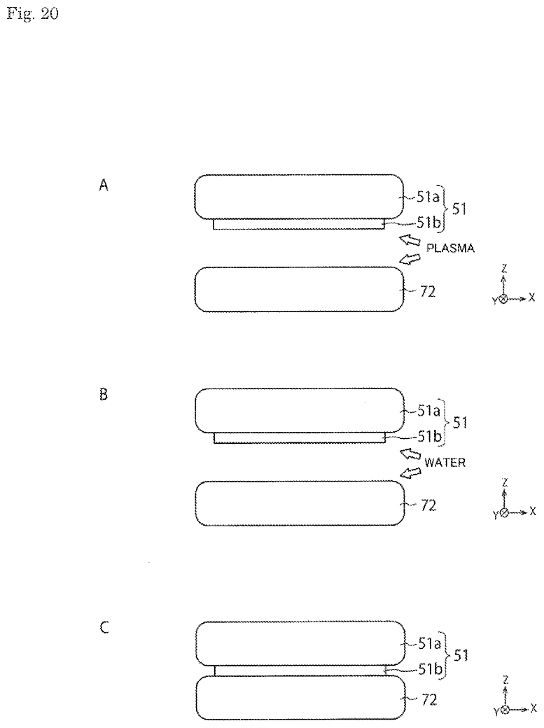

FIG. 20 is a cross-sectional view for explaining the details of the step illustrated in B of FIG. 17, and illustrates how the substrate 51 and the substrate 72 are directly bonded by plasma bonding.

First, as illustrated in A of FIG. 20, the lower surface of the substrate 51 and the upper surface of the substrate 72 are treated with plasma. Next, as illustrated in B of FIG. 20, the lower surface of the substrate 51 and the upper surface of the substrate 72 are treated with water. Next, as illustrated in C of FIG. 20, the lower surface of the substrate 51 is pressed against the upper surface of the substrate 72 to heat these substrates 51 and 72. As a result, the substrate 51 and the substrate 72 are directly bonded by the action of the hydroxide group caused by water. It is to be noted that the substrate 51 and the substrate 72 may be directly bonded by a method other than plasma bonding (for example, room temperature bonding).

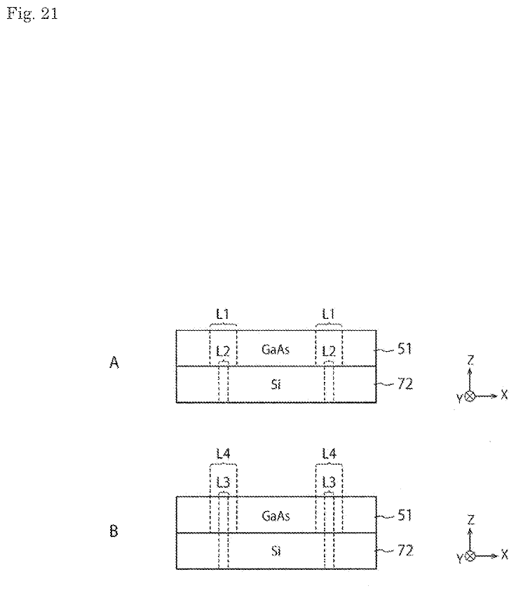

FIG. 21 is a cross-sectional view for explaining the details of the step illustrated in C of FIG. 19, and illustrates how the substrate 51 and the substrate 72 are diced.

In A of FIG. 21, an example of dicing the substrate 51 and the substrate 72 at dicing lines L1 and L2 is illustrated. First, the substrate 51 is cut at the thick dicing lines L1. Next, the substrate 72 is cut at the thin dicing lines L2. This makes it possible to manufacture the light emitting device 1 in which the area of the substrate 51 and the area of the substrate 72 are different from each other as illustrated in FIG. 10.

In B of FIG. 21, an example of dicing the substrate 51 and the substrate 72 at dicing lines L3 and L4 is illustrated. First, the substrate 51 and the substrate 72 are cut at the thin dicing lines L3. Next, the substrate 51 is cut at the thick dicing lines L4. This makes it possible to manufacture the light emitting device 1 in which the area of the substrate 51 and the area of the substrate 72 are different from each other as illustrated in FIG. 10.

As described above, according to the present embodiment, it is possible to manufacture the light emitting device 1 in which the substrate (Si substrate) 72 is provided on the back surface S2 of the substrate (GaAs substrate) 51.

It is to be noted that the method according to the present embodiment is also applicable to manufacturing the light emitting device 1 according to the first to ninth modifications of the first embodiment. For example, the light emitting device 1 according to the fourth modification can be manufactured by adopting the method illustrated in A or B of FIG. 21. Further, the light emitting device 1 according to the fifth to seventh modifications can be manufactured by forming the resin film 73, the lenses 74, the embedded film 75, and so on in the step B of FIG. 17. Further, the light emitting device 1 according to the eighth and ninth modifications can be manufactured by forming the recess 76, the reflective metal film 77, and so on in the step C of FIG. 18.

### Third Embodiment

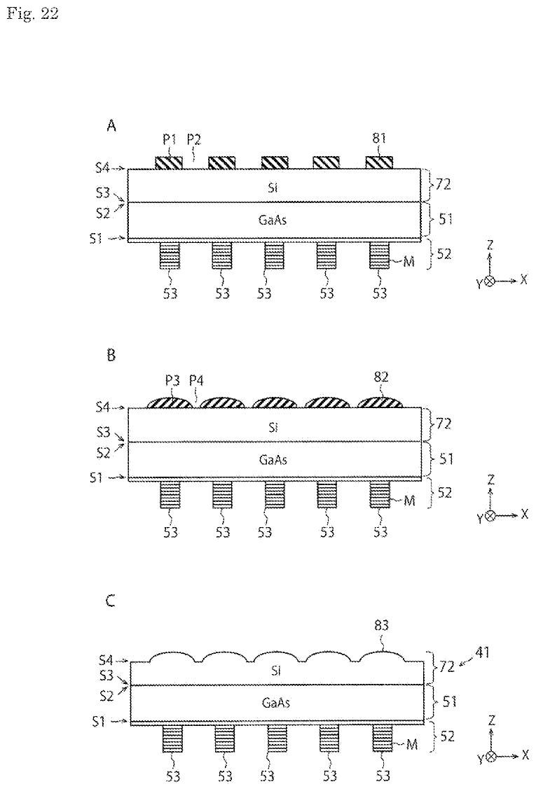

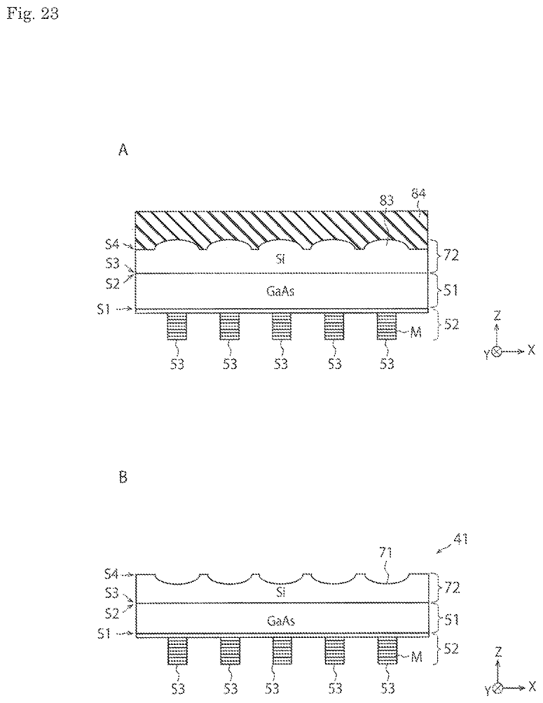

FIGS. 22 and 23 are cross-sectional views illustrating a method of manufacturing the light emitting device 1 according to a third embodiment. In the method according to the present embodiment, the concave lenses (lenses 71) in the first embodiment are formed.

First, the laminated film 52, the light emitting elements 53, and so on are formed on the front surface S1 of the substrate 51, then a resist film 81 are formed on the back surface S4 of the substrate 72, and the resist film 81 is patterned by lithography (A of FIG. 22). As a result, the resist film 81 including a plurality of resist portions P1 and a plurality of openings P2 is formed on the back surface S4 of the substrate 72. These resist portions P1 are formed above the light emitting elements 53.

Next, reflow baking is performed on the patterned resist film 81 (B of FIG. 22). As a result, the resist film 81 changes into a resist film 82 including a plurality of resist portions P3 rounded by surface tension. This resist film 82 includes the plurality of resist portions P3 and a plurality of openings P4.

Next, the resist portions (resist pattern) P3 of the baked resist film 82 is transferred onto the substrate 72 by dry etching (C of FIG. 22). As a result, the back surface S4 of the substrate 72 is processed by dry etching, and a plurality of protrusions 83 having the same shape as the resist portions P3 before dry etching are formed on the back surface S4 of the substrate 72.

Next, a hard mask layer 84 is formed on the back surface S4 of the substrate 72 so as to cover these protrusions 83 (A of FIG. 23). The hard mask layer 84 is, for example, an SOG (Spin On Glass) film.

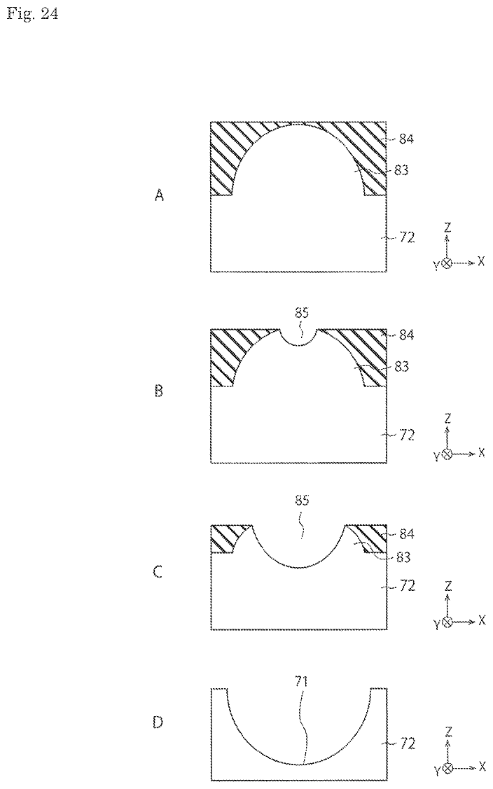

Next, the hard mask layer 84 is gradually removed by dry etching (B of FIG. 23). As a result, the protrusions 83 are exposed from the hard mask layer 84 by dry etching, and the hard mask layer 84 is removed together with the protrusions 83 by the subsequent dry etching, so that the protrusions 83 change into recesses, that is, concave lenses (lenses 71). In this way, the plurality of lenses 71 are formed on the back surface S4 of the substrate 72. The dry etching is performed using, for example, a chlorine-based gas such as BCl₃ gas or Cl₂ gas (B represents boron and Cl represents chlorine). O₂ (oxygen) gas, N₂ (nitrogen) gas, or Ar (argon gas) may be used together with the chlorine-based gas. Details of this step will be described with reference to FIG. 24.

FIG. 24 is a cross-sectional view for explaining the details of the step illustrated in B of FIG. 23.

In A of FIG. 24, the protrusion 83 covered with the hard mask layer 84 is illustrated. When the hard mask layer 84 is gradually removed by dry etching, the protrusion 83 is exposed from the hard mask layer 84 (B of FIG. 24). Since there is a difference in etching rate between the substrate 72 (Si substrate) and the hard mask layer 84 (SOG film), in the subsequent dry etching, the protrusion 83 is etched at a higher etching rate than that of the hard mask layer 84 (C of FIG. 24). As a result, a recess 85 is formed at the upper end of the protrusion 83, the size of the recess 85 gradually increases, and finally the protrusion 83 is removed, so that the recess 85, that is, a concave lens (lens 71) is formed at the position where the protrusion 83 has been removed. In this way, the step illustrated in B of FIG. 23 proceeds.

In the present embodiment, after that, the steps A to C of FIG. 19 in the second embodiment and the subsequent steps are performed. In this way, the light emitting device 1 illustrated in FIG. 4 is manufactured.

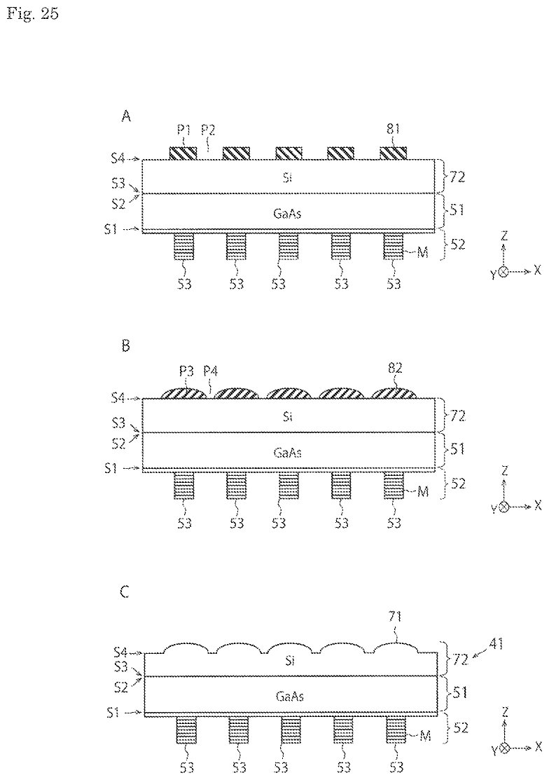

FIG. 25 is a cross-sectional view illustrating a method of manufacturing a light emitting device 1 by way of a modification according to the third embodiment. In the method according to the present embodiment, the convex lenses (lenses 71) in the first embodiment are formed.

First, the laminated film 52, the light emitting elements 53, and so on are formed on the front surface S1 of the substrate 51, then a resist film 81 are formed on the back surface S4 of the substrate 72, and the resist film 81 is patterned by lithography (A of FIG. 25). As a result, the resist film 81 including a plurality of resist portions P1 and a plurality of openings P2 is formed on the back surface S4 of the substrate 72. These resist portions P1 are formed above the light emitting elements 53.

Next, reflow baking is performed on the patterned resist film 81 (B of FIG. 25). As a result, the resist film 81 changes into a resist film 82 including a plurality of resist portions P3 rounded by surface tension. This resist film 82 includes the plurality of resist portions P3 and a plurality of openings P4.

Next, the resist portions (resist pattern) P3 of the baked resist film 82 is transferred onto the substrate 72 by dry etching (C of FIG. 25). As a result, the back surface S4 of the substrate 72 is processed by dry etching, so that a plurality of protrusions having the same shape as the resist portions P3 before dry etching, that is, convex lenses (lenses 71) are formed on the back surface S4 of the substrate 72.

In the present embodiment, after that, the steps A to C of FIG. 19 in the second embodiment and the subsequent steps are performed. In this way, the light emitting device 1 illustrated in FIG. 7 is manufactured.

In this way, since the convex lenses can be formed without performing the step using the hard mask layer 84, the convex lenses can be formed more easily than concave lenses.

It is to be noted that the method illustrated in A of FIG. 22 to B of FIG. 23 can be replaced with another method. Two examples of such a method will be described below.

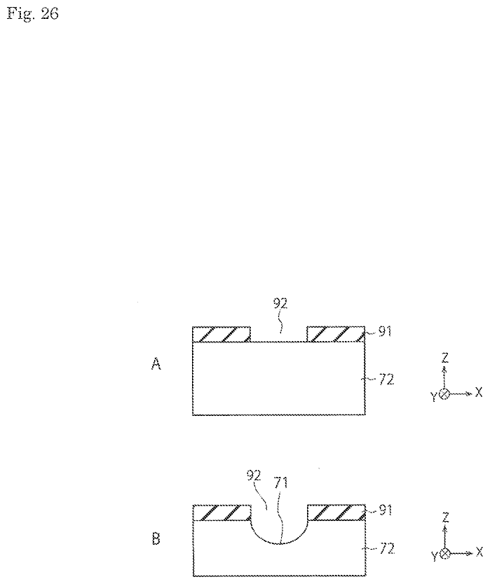

FIG. 26 is a cross-sectional view illustrating a method 1 which is different from the method illustrated in A of FIG. 22 to B of FIG. 23.

First, a hard mask layer 91 is formed on the upper surface (back surface S4) of the substrate 72, and an opening 92 is formed in the hard mask layer 91 (A of FIG. 26). The hard mask layer 91 is, for example, a SiO₂ film. In this method, a plurality of openings 92 are formed in the hard mask layer 91, and one of these openings 92 is illustrated in A of FIG. 26.

Next, the upper surface of the hard mask layer 91 is planarized by CMP (Chemical Mechanical Polishing) (B of FIG. 26). At this time, a phenomenon called “dishing” occurs in which the upper surface of the substrate 72 exposed in the opening 92 is recessed by CMP. As a result, a recess, that is, a concave lens (lens 71) is formed on the upper surface (back surface S4) of the substrate 72 in the opening 92. More specifically, a plurality of concave lenses (lenses 71) are formed on the back surface S4 of the substrate 72 in a plurality of openings 92 of the hard mask layer 91.

In the present embodiment, after that, the hard mask layer 91 is removed, then the steps A to C of FIG. 19 and the subsequent steps in the second embodiment are performed. In this way, the light emitting device 1 illustrated in FIG. 4 is manufactured.

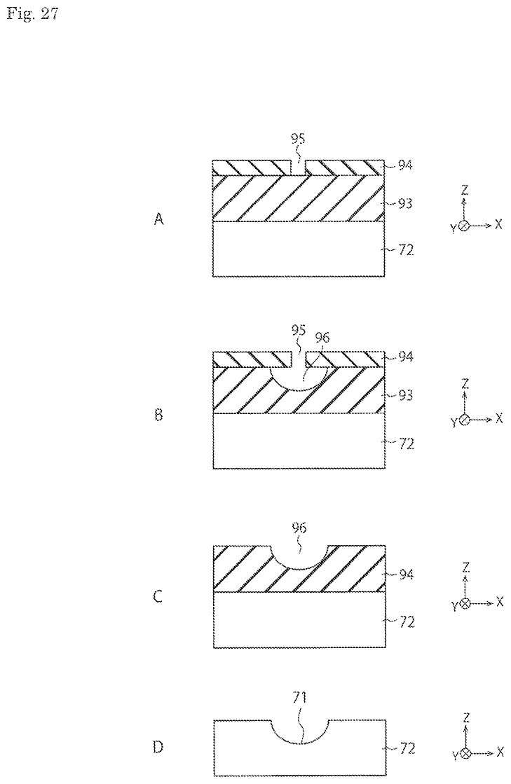

FIG. 27 is a cross-sectional view illustrating a method 2 which is different from the method illustrated in A of FIG. 22 to B of FIG. 23.

First, a first hard mask layer 93 is formed on the upper surface (back surface S4) of the substrate 72, a second hard mask layer 94 is formed on the first hard mask layer 93, and a small opening 95 is formed in the second hard mask layer 94 (A of FIG. 27). The first hard mask layer 93 is, for example, an organic film such as a carbon film. The second hard mask layer 94 is, for example, a SiO₂ film. In this method, a plurality of openings 95 are formed in the second hard mask layer 94, and one of these openings 95 is illustrated in A of FIG. 27.

Next, the first hard mask layer 93 is processed by isotropic etching using the second hard mask layer 94 as a mask (B of FIG. 27). As a result, the first hard mask layer 93 exposed in the opening 95 is isotropically recessed, so that a recess 96 is formed in the first hard mask layer 93.

Next, the second hard mask layer 94 is removed (C of FIG. 27). Next, the recess 96 of the first hard mask layer 93 is transferred onto the substrate 72 by dry etching (D of FIG. 27). As a result, the back surface S4 of the substrate 72 is processed by dry etching, so that a recess having the same shape as the recess 96, that is, a concave lens (lens 71) is formed on the back surface S4 of the substrate 72. More specifically, a plurality of concave lenses (lenses 71) having the same shape as the plurality of recesses 96 are formed on the back surface S4 of the substrate 72.

In the present embodiment, after that, the steps A to C of FIG. 19 in the second embodiment and the subsequent steps are performed. In this way, the light emitting device 1 illustrated in FIG. 4 is manufactured.

As described above, according to the present embodiment, it is possible to form a concave lens or a convex lens as the lens 71.

It is to be noted that although the light emitting device 1 according to the first to third embodiments is used as the light source for the distance measuring device, it may be used in other aspects. For example, the light emitting device 1 according to these embodiments may be used as a light source for an optical device such as a printer, or may be used as a lighting device.

Although the embodiments of the present disclosure have been described above, these embodiments may be implemented with various modifications without departing from the spirit and scope of the present disclosure. For example, two or more embodiments may be combined to be implemented.

It is to be noted that the present disclosure may also have the following configuration.

(1) A light emitting device including:

a first substrate;

a plurality of light emitting elements that are provided on a first surface of the first substrate; and

a second substrate that is provided on a second surface of the first substrate opposite to the first surface.

(2) The light emitting device according to (1), wherein

the first substrate is formed of a first material, and

the second substrate is formed of a second material different from the first material.

(3) The light emitting device according to (1), wherein the second substrate is directly bonded to the first substrate.

(4) The light emitting device according to (1), wherein the first substrate is a semiconductor substrate containing gallium (Ga) and arsenic (As).

(5) The light emitting device according to (1), wherein the second substrate is a semiconductor substrate containing silicon (Si).

(6) The light emitting device according to (1), wherein

the second substrate has a third surface on the first substrate side and a fourth surface opposite to the first substrate, and

the light emitting device further includes a plurality of lenses that are provided on the fourth surface of the second substrate and on which light emitted from the light emitting elements is incident.

(7) The light emitting device according to (6), wherein the lenses are provided on the fourth surface of the second substrate as part of the second substrate.

(8) The light emitting device according to (6), wherein the lenses include at least one of a concave lens, a convex lens, and a flat lens.

(9) The light emitting device according to (6), wherein the plurality of light emitting elements and the plurality of lenses have a one-to-one correspondence so that the light emitted from one light emitting element enters one lens corresponding to the one light emitting element.

(10) The light emitting device according to (6), wherein the light emitted from the plurality of light emitting elements is transmitted through the first substrate from the first surface to the second surface, transmitted through the second substrate from the third substrate to the fourth surface, and then enters the plurality of lenses.

(11) The light emitting device according to (1), wherein the first surface of the first substrate is a front surface of the first substrate, and the second surface of the first substrate is a back surface of the first substrate.

(12) The light emitting device according to (1), wherein the second substrate has a third surface on the first substrate side and a fourth surface opposite to the first substrate, and an area of the third surface of the second substrate is larger than an area of the second surface of the first substrate.

(13) The light emitting device according to (1), wherein the second substrate is bonded to the first substrate via a resin film.

(14) The light emitting device according to (1), further including a plurality of second lenses that are provided on the second surface of the first substrate and on which light emitted from the light emitting elements is incident.

(15) The light emitting device according to (14), wherein the second lenses include at least one of a concave lens and a convex lens.

(16) The light emitting device according to (6), further including a recess that is provided on the fourth surface of the second substrate, wherein the lenses are provided on a bottom surface of the recess.

(17) The light emitting device according to (16), further including a reflective film that is provided on a side surface of the recess.

(18) A method of manufacturing a light emitting device including;

bonding a second substrate to a second surface of a first substrate; and

forming a plurality of light emitting elements on a first surface of the first substrate opposite to the second surface.

(19) The method of manufacturing a light emitting device according to (18), wherein

the second substrate has a third surface on the first substrate side and a fourth surface opposite to the first substrate, and

the method further includes forming, on the fourth surface of the second substrate, a plurality of lenses on which light emitted from the light emitting elements is incident.

(20) The method of manufacturing a light emitting device according to (19), wherein the lenses include at least one of a concave lens, a convex lens, and a flat lens.

(21) The method of manufacturing a light emitting device according to (20), wherein the concave lens is formed by forming a protrusion on the second surface of the second substrate and processing the protrusion into a recess.

(22) The method of manufacturing a light emitting device according to (20), wherein the convex lens is formed by forming a protrusion on the second surface of the second substrate.

(23) The method of manufacturing a light emitting device according to (18), wherein

the first substrate includes a wafer and an epitaxial layer formed on a surface of the wafer, and

the second substrate is bonded to a surface of the epitaxial layer of the first substrate after the epitaxial layer is formed on the surface of the wafer.

(24) The method of manufacturing a light emitting device according to (18), wherein the second substrate is directly bonded to the first substrate.

### REFERENCE SIGNS LIST

1 Light emitting device
2 Image pickup device
3 Control device
11 Light emitting unit
12 Drive circuit
13 Power supply circuit
14 Light emitting optics system
21 Image sensor
22 Image processing unit
23 Image pickup optics system
31 Distance measuring unit
41 LD chip
42 LDD substrate
43 Mounting substrate
44 Heat dissipation substrate
45 Correction lens holder
46 Correction lens
47 Wire
48 Bump
51 Substrate (GaAs substrate)
51a Wafer
51b Epitaxial layer
52 Laminated film
53 Light emitting element
54 Anode electrode
55 Cathode electrode
61 Substrate
62 Connection pad
71 Lens
72 Substrate (Si substrate)
73 Resin film
74 Lens
75 Embedded film
76 Recess
77 Reflective metal film
78 Resin film
79 Glass substrate
80 Mounting device
81 Resist film
82 Resist film
83 Protrusion
84 Hard mask layer
85 Recess
91 Hard mask layer
92 Opening
93 First hard mask layer
94 Second hard mask layer
95 Opening
96 Recess

What is claimed is:

1. A light emitting device, comprising:
a first substrate;
a plurality of light emitting elements that are provided on a first surface of the first substrate; and
a second substrate that is provided on a second surface of the first substrate opposite to the first surface.

2. The light emitting device according to claim 1, wherein
the first substrate is formed of a first material, and
the second substrate is formed of a second material different from the first material.

3. The light emitting device according to claim 1, wherein the second substrate is directly bonded to the first substrate.

4. The light emitting device according to claim 1, wherein the first substrate is a semiconductor substrate containing gallium (Ga) and arsenic (As).

5. The light emitting device according to claim 1, wherein the second substrate is a semiconductor substrate containing silicon (Si).

6. The light emitting device according to claim 1, wherein
the second substrate has a third surface on the first substrate side and a fourth surface opposite to the first substrate, and
the light emitting device further comprises a plurality of lenses that are provided on the fourth surface of the second substrate and on which light emitted from the light emitting elements is incident.

7. The light emitting device according to claim 6, wherein the lenses are provided on the fourth surface of the second substrate as part of the second substrate.

8. The light emitting device according to claim 6, wherein the lenses include at least one of a concave lens, a convex lens, and a flat lens.

9. The light emitting device according to claim 6, wherein the plurality of light emitting elements and the plurality of lenses have a one-to-one correspondence so that the light emitted from one light emitting element enters one lens corresponding to the one light emitting element.

10. The light emitting device according to claim 6, wherein the light emitted from the plurality of light emitting elements is transmitted through the first substrate from the first surface to the second surface, transmitted through the second substrate from the third substrate to the fourth surface, and then enters the plurality of lenses.

11. The light emitting device according to claim 1, wherein the first surface of the first substrate is a front surface of the first substrate, and the second surface of the first substrate is a back surface of the first substrate.

12. The light emitting device according to claim 1, wherein
the second substrate has a third surface on the first substrate side and a fourth surface opposite to the first substrate, and
an area of the third surface of the second substrate is larger than an area of the second surface of the first substrate.

13. The light emitting device according to claim 1, wherein the second substrate is bonded to the first substrate via a resin film.

14. The light emitting device according to claim 1, further comprising a plurality of second lenses that are provided on the second surface of the first substrate and on which light emitted from the light emitting elements is incident.

15. The light emitting device according to claim 14, wherein the second lenses include at least one of a concave lens and a convex lens.

16. The light emitting device according to claim 6, further comprising a recess that is provided on the fourth surface of the second substrate, wherein
the lenses are provided on a bottom surface of the recess.

17. The light emitting device according to claim 16, further comprising a reflective film that is provided on a side surface of the recess.

18. A method of manufacturing a light emitting device, comprising:
bonding a second substrate to a second surface of a first substrate; and
forming a plurality of light emitting elements on a first surface of the first substrate opposite to the second surface.

19. The method of manufacturing a light emitting device according to claim 18, wherein
the second substrate has a third surface on the first substrate side and a fourth surface opposite to the first substrate, and
the method further comprises forming, on the fourth surface of the second substrate, a plurality of lenses on which light emitted from the light emitting elements is incident.

20. The method of manufacturing a light emitting device according to claim 19, wherein the lenses include at least one of a concave lens, a convex lens, and a flat lens.

21. The method of manufacturing a light emitting device according to claim 20, wherein the concave lens is formed by forming a protrusion on the second surface of the second substrate and processing the protrusion into a recess.

22. The method of manufacturing a light emitting device according to claim 20, wherein the convex lens is formed by forming a protrusion on the second surface of the second substrate.

23. The method of manufacturing a light emitting device according to claim 18, wherein
the first substrate includes a wafer and an epitaxial layer formed on a surface of the wafer, and
the second substrate is bonded to a surface of the epitaxial layer of the first substrate after the epitaxial layer is formed on the surface of the wafer.

24. The method of manufacturing a light emitting device according to claim 18, wherein the second substrate is directly bonded to the first substrate.
